(19) United States
(12) Patent Application Publication
(10) Pub. No.: US 2026/0004960 A1
(43) Pub. Date: Jan. 1, 2026

(54) COIL ARRANGEMENT ON A MULTILAYER CIRCUIT BOARD, AND METHOD FOR PRODUCING A COIL ARRANGEMENT

(71) Applicant: Turck Holding GmbH, Halver (DE)

(72) Inventor: Michael Faber, Altena (DE)

(73) Assignee: Turck Holding GmbH, Halver (DE)

(21) Appl. No.: 19/245,528

(22) Filed: Jun. 23, 2025

(30) Foreign Application Priority Data
Jun. 26, 2024 (DE) 10 2024 117 999.6

(51) Int. Cl. H01F 17/00; H01F 27/28

(52) U.S. Cl. CPC H01F 17/0013; H01F 27/2804; H01F 2027/2809

(57) ABSTRACT

A multilayer circuit board comprising a coil arrangement, the coil arrangement including a first coil having at least two turns, wherein the turns of the first coil are arranged above one another in separate layers of the multilayer circuit board and have the same first diameter; and a second coil having at least two turns, wherein the turns of the second coil are arranged above one another in separate layers of the multilayer circuit board and have the same second diameter; wherein the turns of the first coil and the turns of the second coil are arranged at least partially in the same layers of the multilayer circuit board; and wherein each turn of the turns of the first coil and the turns of the second coil is formed entirely in a respective single plane.

### CROSS REFERENCE TO RELATED APPLICATION

This application claims priority to German patent application 10 2024 117 999.6 filed on Jun. 26, 2024, which is hereby incorporated by reference in its entirety.

### TECHNICAL FIELD

The present disclosure relates to a coil arrangement on a multilayer circuit board and to a method for producing a coil arrangement. The disclosure relates to the fields of coil technology and sensor systems, for example inductive proximity switches or position sensors.

### BACKGROUND

Coils are used in a multiplicity of different applications, for example for inductive sensors. They are used in this context to emit and evaluate electromagnetic fields. Coils may be manufactured in various ways, for instance by winding copper wire or in a printed circuit board technology with printed copper conductor tracks. It is possible in this case to obtain higher reproducibility, a wide variety of design variance, particularly good economic efficiency and higher long-term stability for coils in printed circuit board technology.

In known printed coils, the turns are formed with different diameters, for instance with a spiral-shaped profile of the printed conductor tracks. As an alternative, provision is made for wound coils in the form of layer coils, wherein the winding technique that is used then very substantially determines the properties of the coil quality and the propagation of the electromagnetic field. However, in wound coils, challenges arise due to difficult reproducibility, high costs and high outlay in terms of the further processing of the coils in subsequent manufacturing processes.

US 2008/0272982 A1 describes a high-impedance surface with embedded elements such as capacitors and inductors that is intended to improve antenna performance and reduce interference. By way of example, the high-impedance surface may be brought close to the antenna. The embedded elements are then intended to minimize the propagation of surface waves and at the same time improve impedance matching so as to reduce energy consumption and increase bandwidth.

US 2005/0195060 A1 discloses constructing turns with the aid of a multilayer printed circuit board. Conductor tracks are arranged on various insulating layers of the PCB that are supplemented with additional conductive metal layers to form a winding that can handle higher currents more efficiently.

US 2011/0253310 A1 proposes a device for an arrangement of induction coils in a plasma processing system. Coils are formed on separate printed circuit boards that are arranged above one another. Each PCB plane contains a coil arrangement comprising circularly intertwined non-circular coils. The coils arranged in multiple layers can be operated independently of one another in order to optimize plasma density in the radial direction and to achieve improved plasma uniformity.

### SUMMARY

Provided is a multilayer circuit board comprising a coil arrangement. The coil arrangement incudes a first coil having at least two turns, wherein the turns of the first coil are arranged above one another in separate layers of the multilayer circuit board and have a same first diameter; and a second coil having at least two turns, wherein the turns of the second coil are arranged above one another in separate layers of the multilayer circuit board and have a same second diameter. The turns of the first coil and the turns of the second coil are arranged at least partially in the same layers of the multilayer circuit board. Each turn of the turns of the first coil and the turns of the second coil is formed entirely in a respective single plane.

Provided is a method for producing a coil arrangement. The method comprises producing a first coil having at least two turns such that the turns of the first coil are arranged above one another in separate layers of a multilayer circuit board and have a same first diameter; and producing a second coil having at least two turns such that the turns of the second coil are arranged above one another in separate layers of the multilayer circuit board and have a same second diameter. The turns of the first coil and the turns of the second coil are arranged at least partially in the same layers of the multilayer circuit board. Each turn of the turns of the first coil and the turns of the second coil is formed entirely in a respective single plane.

### BRIEF DESCRIPTION OF THE DRAWINGS

In the drawings:

FIG. 1 (i) to (xiv) show a schematic and exemplary illustration of fourteen layers of a multilayer circuit board in a top view, respectively, the circuit board comprising one exemplary embodiment of the coil arrangement;

FIG. 2 shows schematically one exemplary embodiment of an inductive position sensor with the coil arrangement;

FIG. 3 shows a schematic and exemplary illustration of three layers of said multilayer circuit board in a side view; and

FIG. 4 shows schematically and exemplary a flowchart for a method for producing said circuit board comprising said coil arrangement.

### DETAILED DESCRIPTION

In the following, details are set forth to provide a more thorough explanation of the disclosure. However, it will be apparent to those skilled in the art that these implementations may be practiced without these specific details. In other instances, well-known structures and devices are shown in block diagram form or in a schematic view rather than in detail in order to avoid obscuring the disclosure. In addition, features described hereinafter may be combined with each other, even if described with respect to different figures, unless specifically noted otherwise.

Equivalent or like elements or elements with equivalent or like functionality are denoted in the following description with equivalent or like reference numerals. As the same or functionally equivalent elements are given the equivalent or like reference numbers in the figures, a repeated description for elements provided with the equivalent or like reference numbers may be omitted. Hence, descriptions provided for elements having the equivalent or like reference numbers are mutually exchangeable.

Directional terminology, such as “top,” “bottom,” “below,” “above,” “front,” “behind,” “back,” “leading,” “trailing,” etc., may be used with reference to the orientation of the figures being described. Because parts of the disclosure, described herein, can be positioned in a number of different orientations, the directional terminology is used for purposes of illustration and is in no way limiting. It is to be understood that other implementations may be utilized, and structural or logical changes may be made without departing from the scope defined by the claims. The following detailed description, therefore, is not to be taken in a limiting sense.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

In implementations described herein or shown in the drawings, any direct electrical connection or coupling, e.g., any connection or coupling without additional intervening elements, may also be implemented by an indirect connection or coupling, e.g., a connection or coupling with one or more additional intervening elements, or vice versa, as long as the general purpose of the connection or coupling, for example, to transmit a certain kind of signal or to transmit a certain kind of information, is essentially maintained. Features from different implementations may be combined to form further implementations. For example, variations or modifications described with respect to one of the implementations may also be applicable to other implementations unless noted to the contrary.

The terms “substantially” and “approximately” may be used herein to account for small manufacturing tolerances (e.g., within 5%) that are deemed acceptable in the industry without departing from the aspects of the implementations described herein. For example, a resistor with an approximate resistance value may practically have a resistance within 5% of that approximate resistance value.

In the present disclosure, expressions including ordinal numbers, such as “first”, “second”, and/or the like, may modify various elements. However, such elements are not limited by the above expressions. For example, the above expressions do not limit the sequence and/or importance of the elements. The above expressions are used merely for the purpose of distinguishing an element from the other elements. For example, a first box and a second box indicate different boxes, although both are boxes. For further example, a first element could be termed a second element, and similarly, a second element could also be termed a first element without departing from the scope of the present disclosure.

One object of the present disclosure may be to provide a coil arrangement that makes it possible to combine the advantages of wound and printed coils and that moreover allows simple and easily reproducible manufacture.

A coil arrangement on a multilayer circuit board may be provided, optionally configured for use with or as part of an inductive position sensor, said coil arrangement comprising a first coil having at least two turns, which are arranged above one another in separate layers of the multilayer circuit board. The coil arrangement furthermore comprises a second coil having at least two turns, which are arranged above one another in separate layers of the multilayer circuit board. In this case, the turns of the first coil and the turns of the second coil are arranged at least partially in the same layers of the multilayer circuit board.

Optionally, in this case, the first coil is embodied as a transmitting coil and the second coil is embodied as a receiving coil of an inductive position or proximity sensor.

The design of the coils can make it possible to form a virtually cylindrical coil shape on the multilayer circuit board, optionally for printed coils.

The first and the second coil are optionally embodied such that their turns are each arranged above one another such that they lie directly above one another in a plan view of the multilayer circuit board or in a corresponding projection along a longitudinal axis of the coils perpendicular to the plane of the multilayer circuit board.

Optionally, the feature whereby the turns are arranged above one another in the layers of the multilayer circuit board may be understood to mean that they are substantially congruent in a projection along the longitudinal axis of the coil.

The turns of the coils may furthermore be formed in this case such that they all have the same size and shape. By way of example, the turns may be round and in the process have the same diameter and the same center point in the plane of the multilayer circuit board. The turns may also have a different geometry, for instance in the form of polygons, wherein they may then optionally be formed congruently with respect to one another or may be formed in a manner rotated by a specific angle relative to one another in the different layers.

By way of example, the turns of a coil may each be arranged in successive “copper layers,” with an insulating layer being arranged in each case between the copper layers. The copper layers in this case are those layers of the multilayer circuit board in which the electrically conductive turns of the coils are formed from an electrically conductive material, such as copper for example. Additional conductive regions may optionally be provided in the insulating layers, optionally for contact-connecting the turns and other elements in the further layers, which are otherwise insulated from one another.

At least one or some of the turns of the first coil can be arranged in the same layer of the multilayer circuit board as at least one turn of the second coil. In other words, the respective longitudinal extents of the first and second coil intersect in the direction of their longitudinal axis (or their central axis).

In one embodiment, the turns of the first coil can have a common first diameter and the turns of the second coil have a common second diameter. In this case, the first and second coil furthermore have a common longitudinal axis.

The arrangement along a common longitudinal axis can mean optionally that the first and second coil and, where applicable, further coils of the coil arrangement have the same center point in a projection in the plane of the multilayer circuit board.

Optionally, the first and second diameter of the first and second coil can be of different sizes, such that, in at least one layer of the multilayer circuit board, a turn of the first coil is enclosed by a turn of the second coil or vice versa.

In the case of a circular shape of a turn, the diameter and, where applicable, the center point can be defined in accordance with conventional geometric considerations.

The turns may also be embodied in some other way, for example as polygons. The diameter and the center point may then be defined in a manner known per se, for instance on the basis of the periphery of the polygon.

In a further embodiment, the coil arrangement furthermore can comprise a third coil having at least two turns, which are arranged above one another in separate layers of the multilayer circuit board. In this case, the turns of the third coil and the turns of the first and/or second coil can be arranged at least partially in the same layers of the multilayer circuit board.

The third coil may be embodied for example as a further receiving coil of a position or proximity sensor.

By way of example, it is possible to provide an inductive factor-1 sensor by combining three laid-out layer coils on a multilayer circuit board. One of the coils is used as a transmitting coil and two further coils serve as receiving coils whose signals are phase-shifted by 180°.

The third coil may furthermore be embodied analogously to the first and/or second coil, but optionally with a third diameter for all turns that differs from the first and second diameter of the first and second coil.

The turns of the third coil may optionally be of the same size and shape and be arranged exactly above one another.

The turns of the third coil may furthermore—like the turns of the first and/or second coil—be formed in mutually adjacent copper layers of the multilayer circuit board.

At least one or some of the turns of the third coil can be arranged in the same layer of the multilayer circuit board as at least one turn of the first and/or second coil. In this case, the longitudinal extent of the third coil therefore intersects the longitudinal extent of the first and/or second coil in the direction of its longitudinal axis (or its central axis).

Provision may furthermore be made for turns of the first, second and third coil to be arranged in at least one layer of the multilayer circuit board. These turns optionally have the same center point and different diameters, such that they surround one another.

By way of example, the first coil, which is embodied optionally as a transmitting coil of a position or proximity sensor, may have a diameter that lies between the second and third diameter of the second and third coil, which are embodied optionally as receiving coils of the sensor. In this case, the first coil is thus arranged between the second coil and the third coil, one of which has a larger diameter, and the other of which has a smaller diameter.

In one development, all of the turns of the first, second and/or, where applicable, of the third coil can be each arranged in different layers, optionally in successive layers.

The coils thus optionally do not have any spiral-shaped turns in a single plane, as is typically provided in the case of printed coils, but rather the turns are distributed over multiple, optionally adjacent copper layers of the multilayer circuit board.

The turns of a coil are contact-connected in a manner known per se by the insulating layers arranged between successive layers.

In one embodiment, all of the turns of the first, second and/or, where applicable, of the third coil in the respective different layers can be formed as substantially complete turns.

Optionally, complete turns can be assumed in the present case if the conductive material thereof runs around an angle of substantially 360°, measured from the center point of the turn. In order to be able to distribute the turns over multiple layers and contact-connect them to one another, the turns are typically not formed completely over 360°, but rather may for example have an “opening” over an angle of at most 45°, preferably at most 30°, more preferably at most 15°, measured from the center point of the turn. The turns may comprise an input pin for receiving electrical energy and may comprise an output pin for outputting electrical energy. The two pins may be formed at an end of the turn, respectively. The two ends of the turn may be spaced apart from each other (in order to avoid a short circuit).

The coil arrangement may optionally be optimized for installation in a housing, for instance by adapting the geometry of the coils to the shape of the cross section of the housing. This is particularly relevant when the housing comprises metal, which may interfere with the transmission and/or reception properties of the coils.

By way of example, in the case of a round housing cross section, the coil geometry may be square for at least one coil; optionally, at least one first and/or third coil embodied as a receiving coil may be square; in this case, maximum use can be made of the area available in the cross section of the housing at the corners of the square, while the sides of the square are arranged at a distance from the housing and are therefore less subject to interference from metal material.

Provision may furthermore be made, in the case of a square or rectangular housing cross section, for a square or rectangular shape of at least one of the coils to be rotated by 45° in relation thereto, such that as many sections of the coil as possible are as far away from the housing as possible, wherein at the same time the corner points of the winding geometry make full use of the available area.

Other geometric shapes of the coils or of the turns are also conceivable, optionally in order to ensure that they are not arranged too close to a potentially interfering metal housing.

In one development, at least some of the turns of the first and second coil, and where applicable of the third coil, are arranged in overlapping layers of the multilayer circuit board. Here, turns in each case one turn of all of the coils are optionally arranged in at least one layer of the multilayer circuit board.

The coils are optionally arranged to be at least partially “nested” inside one another. In other words, the longitudinal extents of the first, second and, where applicable, third coil overlap in the direction of their longitudinal axis (or their central axis).

The coil arrangement described here may enable good reproducibility, inexpensive production for mass products, a particularly great degree of design freedom in terms of the coil geometries, a flexible number of layer coils on a multilayer circuit board and the possibility of realizing a complete coil system for inductive proximity switches or position sensors with factor-1 behavior. This enables new optimized design and installation properties of a sensor with printed coil systems.

The coil arrangement makes it possible to form printed circuit board coils such that they essentially have the properties of a wound layer coil in a multilayer structure. It can be additionally possible to implement multiple coils having different diameters when the coils are embodied as a layer coil on a multilayer circuit board. A complete factor-1 coil system on a multilayer circuit board is thus possible.

The layer coil on a multilayer circuit board may be realized optionally by positioning one turn per copper layer exactly geometrically below the respective preceding one. A layer coil having minimal spacings between the windings is thereby produced on the multilayer circuit board.

Multiple layer coils may be formed on a multilayer circuit board. By way of example, at least three laid-out layer coils may be used to produce a complete coil system for an inductive factor-1 sensor on a printed circuit board.

The inductive position sensor comprises a coil arrangement according to the present description.

In this case, optionally, the first coil of the coil arrangement is embodied as a transmitting coil and the second coil is embodied as a receiving coil. A third coil may optionally be embodied as a further receiving coil. Provision may be made for a control unit for the inductive position sensor.

The position sensor may be embodied for example as a proximity sensor or proximity switch that is configured to detect a target object, optionally a metal target object, in a detection region and to output for example a signal depending on the detected target object, for instance a switching signal.

For this purpose, provision may be made for a control unit that controls the coil arrangement.

In the method for producing a coil arrangement or for producing a multilayer circuit board, optionally for an inductive position sensor, a first coil having at least two turns is produced such that the turns are arranged above one another in separate layers of the multilayer circuit board, and a second coil having at least two turns is produced such that the turns are arranged above one another in separate layers of the multilayer circuit board. In this case, the turns of the first coil and the turns of the second coil are arranged at least partially in the same layers of the multilayer circuit board.

The method is optionally configured to produce a coil arrangement according to the present description. It therefore may provide the same advantages as the coil arrangement, and may be developed in the same way. Conversely, the advantages and developments of the method may be transferred to the coil arrangement in the same way.

The individual windings or turns of the first coil (all) have the same diameter and the individual windings or turns of the second coil also (all) have the same diameter which may be different from the diameter of the turns of the first coil. The windings of the individual coils may be placed in adjacent layers of the multilayer board. This may result in cylindrical coils on a multilayer PCB (printed circuit board).

A multilayer circuit board (also: multilayer PCB) may be defined as a printed circuit board consisting of or comprising more than two conductive layers (also known as layers or copper layers), which may be separated from each other by insulating material(s) and may be laminated together under heat and/or pressure.

A winding or turn may be defined as an individual loop or turn of a conductive material from which the coil is made. A winding or turn may have a round, optionally circular, or a polygonal shape.

A layer may be defined as an individual layer within a multilayer PCB on which conductive tracks and other elements may be applied, i.e. which may comprise conductive tracks and other elements (such as windings or turns of coils).

In a further embodiment, at least one of the first and/or second and/or, where applicable, the third coil has a polygonal geometry.

The geometry of the turns may optionally be square or rhombic. The geometry of the turns may optionally be round, optionally circular.

The turn may be a flat turn, i.e. formed entirely within one plane (wherein a longitudinal axis of the respective coil may be perpendicular to said plane). The longitudinal axis may be the center axis of the turn, optionally of all turns, and thus of the respective coil(s).

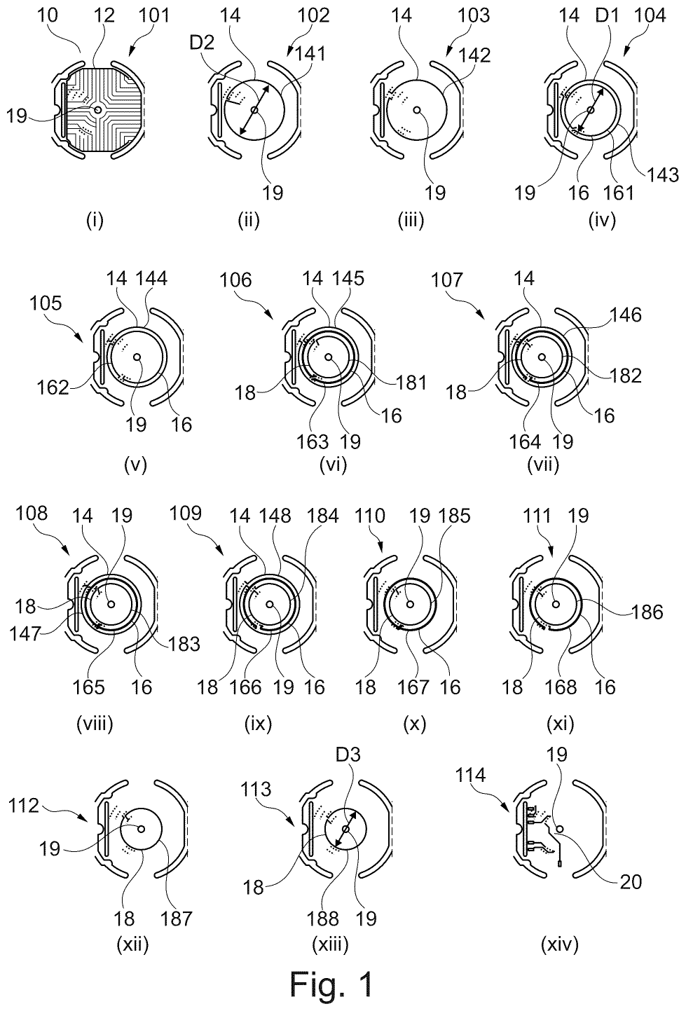

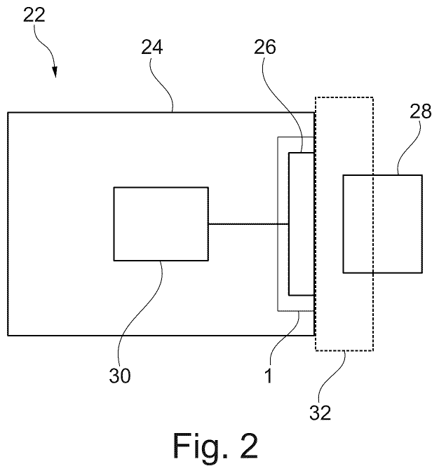

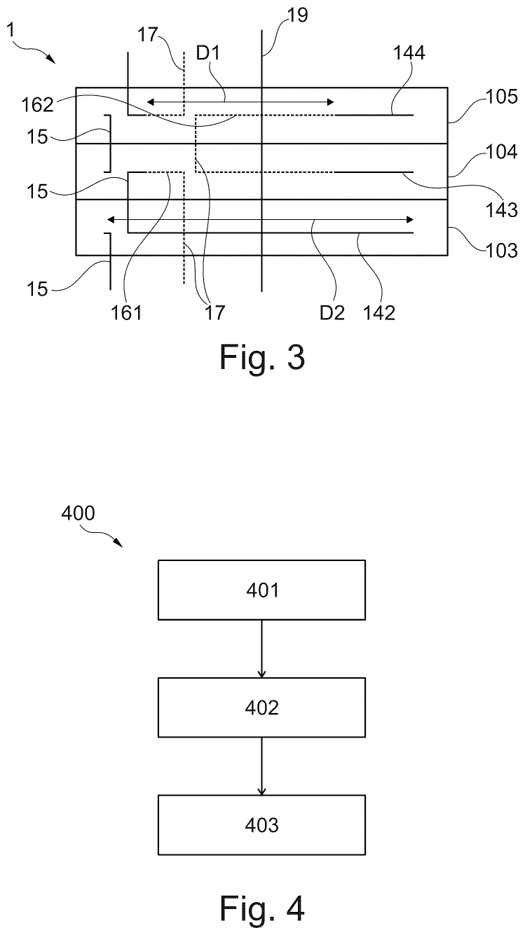

The structure of a multilayer circuit board 1 with one exemplary embodiment of the coil arrangement is explained with reference to FIG. 1 (i) to (xiv), FIG. 2, and FIG. 3. The illustrations that are shown of the structure of the layers 101-114 of the multilayer circuit board 1 should be understood as just being schematic.

In the exemplary embodiment, the coil arrangement 10 has three coils 14, 16, 18.

The coil arrangement 10 is designed for use in an inductive position sensor 22, as explained in more detail below with reference to FIG. 2.

In this case, a first coil 16 is embodied as a transmitting coil.

In this case, a second coil 14 is embodied as a first receiving coil. In the exemplary embodiment, it has a larger diameter D2 than the diameter D1 of the first coil 16.

A third coil 18 is embodied as a second receiving coil. In the exemplary embodiment, it has a smaller diameter D3 than the diameter D1 of the first coil 16.

All turns 161-162 of the first coil 16 have the same diameter D1. All turns 141-142 of the second coil 14 have the same diameter D2. All turns 181-182 of the third coil 18 have the same diameter D3. As can be gathered from FIG. 1, each turn of the turns 141-148, 161-168, 181-188 of the first, second and third coil 14, 16, 18 is flat, i.e. is formed entirely in a respective single plane, i.e. in only one plane that is entirely arranged within one of the layers 101-114 of the circuit board 1. This may also be seen in FIG. 3 schematically showing three layers 103-105 of the circuit board 1. While only some layers 103-105 and some turns 142-144, 161, 162 of the first and the second coils 14, 16 are shown in FIG. 3, the description given with respect to FIG. 3 applies mutatis mutandis to the other layers 101, 102, 106-114.

In the first layer 101 illustrated in FIG. 1 (i), the coil arrangement 10 has a shielding mesh 12. This is embodied in a manner known per se and is configured optionally to shield electromagnetic fields.

The coil arrangement 10 is configured to be installed in a housing of the position sensor 22 such that the shielding mesh 12 is oriented forwards, that is to say optionally towards the active front surface of the sensor 22, in order to shield high-frequency interference from the coils 14, 16, 18, that is to say away from the direction of the desired detection.

The coils 14, 16, 18 are each formed here such that all of their circular turns 141-148, 161-168, 181-188 each have the same first, second and, where applicable, third diameters D1-D3, and that their center points are arranged along the same axis 19. This axis 19 is arranged perpendicular to the plane or surface of the multilayer circuit board 1 as well as its respective layers 101-114 and therefore defines a common longitudinal axis 19 for all three coils 14, 16, 18 and their respective turns 141-148, 161-168, 181-188.

The coils 14, 16, 18 are therefore formed substantially analogously to cylindrical coils, wherein their maximum length is predefined by the thickness of the multilayer circuit board 1 measured along the axis 19.

In the example, the longitudinal extents of the coils 14, 16, 18 overlap, wherein turns 141-148, 161-168 of the first and second coil 14, 16, of the second and third coil 14, 18 or of all three coils 14, 16, 18 are arranged partially in individual layers 101-114 of the multilayer circuit board 1. Moreover, provision is made for layers 101-114 of the multilayer circuit board 1 that have only one turn 141-148, 181-188 of the second coil 14 or third coil 18.

In the example, starting from the shielding mesh 12, the second coil 14 first begins in terms of its longitudinal extent, then the first coil 16 begins with a smaller diameter than the second coil 14, then the third coil 18 begins with an even smaller diameter. The longitudinal extent of the second coil 14, which extends as far as the layer 109 shown in (ix) of FIG. 1, then ends, then the longitudinal extent of the first coil 16, which extends as far as the layer 111 shown in (xi) of FIG. 1, ends, and then the longitudinal extent of the third coil 18, which extends as far as the layer 113 shown in (xiii) of FIG. 1, ends.

In other exemplary embodiments, the coil arrangement 10 may be embodied with coils in a different order and/or with different size ratios of the coils.

The described structure of the coil arrangement on a multilayer circuit board 1 also makes it possible to provide further coils. In this case, provision may be made for different diameters and numbers of turns, for example with a winding diameter adapted to the size of the circuit board 1 and/or with a number of (copper) layers or of turns produced adapted to the thickness of the circuit board 1. The geometries of the coils may also be embodied differently.

Moreover, the coils 14, 16, 18 may be positioned with respect to one another virtually as desired along their longitudinal axis 19, at least within the thickness of the multilayer circuit board 1, such that the installation properties of the sensor can be optimized by the position of the coils 14, 16, 18.

One exemplary embodiment of an inductive position sensor with the coil arrangement is explained with reference to FIG. 2. In this case, the exemplary embodiment of the coil arrangement 10 explained above is taken as a starting point.

The inductive position sensor 22 has a coil arrangement 26 that corresponds substantially to a coil arrangement 10 according to the exemplary embodiment explained above.

It furthermore has a control unit 30 that is coupled to the coil arrangement 10 and controls it such that any penetration or change in position of a target object 28 in a detection region 32 can be detected. The control unit 30 is configured to output a signal depending on the detected target object 28, for instance a switching signal, to a further device, or to output a signal to a superordinate control system.

In the example, the inductive position sensor 22 has a housing 24, which may for example be made of metal.

In the example, the coil arrangement 26 is adapted to the cross-sectional geometry of the housing 24.

In the example, provision is made for a circular housing cross section. In this case, the receiver coils 14, 18 of the coil arrangement 26 can be square, such that only the corner points are arranged close to the housing 24, and the sides of the square are somewhat further away therefrom. This reduces the influence of inference caused by the metal housing 24 on the detection capability of the sensor 22.

In a further example, provision may be made for a square housing cross section. Receiver coils 14, 18, which are likewise square, of the coil arrangement 26 are rotated 45° relative to the geometry of the housing cross section, such that the corners of the coils 14, 18 are arranged close to the side surfaces of the square housing cross section, while the sides of the coils 14, 18 are further away from the corners of the housing cross section. This also avoids interference caused by the metal housing material.

In FIG. 4 a flowchart for a method 400 for producing a coil arrangement 10 is shown. The method 400 comprises a first step 401, a second step 402, and a third step 402. In the first step 401 a first coil 16 is produced. The first coil 16 has at least two turns 161-168 such that or wherein the turns 161-168 of the first coil 16 are arranged above one another in separate layers 101-114 of a multilayer circuit board 1 and have a same first diameter D1. In the second step 402 a second coil 14 is produced. The second coil 14 has at least two turns 141-148 such that or wherein the turns 141-148 of the second coil 14 are arranged above one another in separate layers 101-114 of the multilayer circuit board 1 and have a same second diameter D2. In the third step 403 a third coil 18 is produced. The third coil 18 has at least two turns 181-188 such that or wherein the turns 181-188 of the third coil 18 are arranged above one another in separate layers 101-114 of the multilayer circuit board 1 and have a same third diameter D3. The turns 161-168 of the first coil 16, the turns 141-148 of the second coil 14, and/or the turns 181-188 of the third coil 18 are arranged at least partially in the same layers 101-114 of the multilayer circuit board 1. Each turn of the turns 161-168 of the first coil 16 are formed entirely in a respective single plane. Each turn of the turns 141-148 of the second coil 14 are formed entirely in a respective single plane. Each turn of the turns 181-188 of the third coil 18 are formed entirely in a respective single plane. While the method was described as comprising three steps 401-403, it should be noted that those steps may be performed simultaneously. It is for example possible that the circuit board 1 is produced layer after layer 101-114.

### REFERENCE SYMBOLS

1 Multilayer circuit board
101-114 Layers of the multilayer circuit board
10 Coil arrangement
12 Shielding mesh
14 Second coil (receiver coil, large)
141-148 Turns of the second coil
15 pins connecting turns of first coil
16 First coil (transmitting coil)
161-168 Turns of the first coil
17 pins connecting turns of second coil
18 Third coil (receiving coil, small)
181-188 Turns of the third coil
19 Longitudinal axis
20 Electrical contact connection
22 Inductive position sensor
24 Sensor housing
26 Coil arrangement
28 Target object
30 Control unit
32 Detection region
D1 Diameter of the first coil
D2 Diameter of the second coil
D3 Diameter of the third coil

What is claimed is:

1. A multilayer circuit board comprising a coil arrangement, the coil arrangement including:
a first coil having at least two turns, wherein the turns of the first coil are arranged above one another in separate layers of the multilayer circuit board and have a same first diameter; and
a second coil having at least two turns, wherein the turns of the second coil are arranged above one another in separate layers of the multilayer circuit board and have a same second diameter;
wherein the turns of the first coil and the turns of the second coil are arranged at least partially in the same layers of the multilayer circuit board;
wherein each turn of the turns of the first coil is formed entirely in a respective single plane, and wherein each turn of the turns of the second coil is formed entirely in a respective single plane.

2. The multilayer circuit board according to claim 1, wherein the first coil and second coil have a common longitudinal axis.

3. The multilayer circuit board according to claim 1,
the coil arrangement further including a third coil having at least two turns, wherein the turns of the third coil are arranged above one another in separate layers of the multilayer circuit board and have a same third diameter;
wherein the turns of the third coil and the turns of at least one of the first coil and the second coil are arranged at least partially in the same layers of the multilayer circuit board; and
wherein each turn of the turns of the third coil is formed entirely in a respective single plane.

4. The multilayer circuit board according to claim 1, wherein all turns of the first coil are arranged in different layers of the multilayer circuit board.

5. The multilayer circuit board according to claim 4, wherein all turns of the first coil are arranged in successive layers of the multilayer circuit board.

6. The multilayer circuit board according to claim 1, wherein all turns of the second coil are arranged in different layers of the multilayer circuit board.

7. The multilayer circuit board according to claim 6, wherein all turns of the second coil are arranged in successive layers of the multilayer circuit board.

8. The multilayer circuit board according to claim 1, wherein all of the turns of at least one of the first coil and second coil are formed as substantially complete turns.

9. The multilayer circuit board according to claim 1, wherein at least one of the first coil and the second coil has a polygonal geometry.

10. An inductive position sensor comprising the multilayer circuit board according to claim 1.

11. A method for producing a coil arrangement, the method comprising:
producing a first coil having at least two turns such that the turns of the first coil are arranged above one another in separate layers of a multilayer circuit board and have a same first diameter; and
producing a second coil having at least two turns such that the turns of the second coil are arranged above one another in separate layers of the multilayer circuit board and have a same second diameter;
wherein the turns of the first coil and the turns of the second coil are arranged at least partially in the same layers of the multilayer circuit board; and
wherein each turn of the turns of the first coil are formed entirely in a respective single plane, and wherein each turn of the turns of the second coil are formed entirely in a respective single plane.
